(19) United States
(12) Patent Application Publication
(10) Pub. No.: US 2020/0285782 A1
(43) Pub. Date: Sep. 10, 2020

(54) ARRANGEMENT AND METHOD FOR CONFIGURING A TECHNICAL SYSTEM

(71) Applicant: Siemens Aktiengesellschaft, Munchen (DE)

(72) Inventor: Edgar Fries, Neunkirchen am Brand (DE)

(21) Appl. No.: 16/809,907

(22) Filed: Mar. 5, 2020

(30) Foreign Application Priority Data
Mar. 7, 2019 (EP) 19161326.4

(51) Int. Cl. G06F 30/10; G06F 30/27

(52) U.S. Cl. CPC G06F 30/10; G06N 3/08; G06F 30/27

(57) ABSTRACT

An optimized and automated design of technical installations to be planned individually is provided. For this purpose, operating parameters are first of all recorded in pre-existing technical installations and stored centrally. If the intention is to plan a new technical installation, then the specifications for the new installation may be compared with the previously recorded operating parameters in order to efficiently generate an optimum configuration of the new technical installation.

### CROSS-REFERENCE TO RELATED APPLICATIONS

This application claims priority to EP Application No. 19161326.4, having a filing date of Mar. 7, 2019, the entire contents of which are hereby incorporated by reference.

### FIELD OF TECHNOLOGY

The following relates to an arrangement and to a method for configuring a technical system. The following relates in particular to the configuration or the implementation of a technical system to be designed individually.

### BACKGROUND

The increasing complexity of technical systems, such as for example complex installations, is accompanied by an increase in the requirements in terms of the implementation and development of such complex technical systems. An increasing number of boundary conditions, in particular technical parameters, need to be taken into consideration in this case. Such parameters are for example surrounding temperatures, vibrations, interfering variables from adjacent systems to which the technical system is exposed, or else an aging behavior or failure rates of components that are used. These and other parameters have a considerable influence on the implementation of a technical system to be newly designed. In order to avoid problems with or even premature failure of a technical system, the resources that are used have to be dimensioned and designed to be large enough. In order to prevent problems with or premature failure of a technical system, the resources that are used are generally somewhat overdimensioned. This however entails additional costs and possibly also additional necessary installation space. On the other hand, underdimensioning the resources that are used would increasingly lead to problems with and possibly to a breakdown of the technical system.

It is therefore desirable to obtain information that is as precise as possible about expected operating behavior of a technical system and of the resources that are used. It is furthermore desirable to design a technical system to be newly designed as optimally as possible, that is to say neither over dimensioned nor under dimensioned.

### SUMMARY

Against this background, an aspect relates to provide an arrangement and a method for configuring a technical system that allows a configuration of a technical system to be newly designed that is as optimum as possible.

According to a first aspect, what is provided is an arrangement for configuring a technical system. The arrangement comprises a number of at least one recording device, a storage device and a configuration device. The recording devices are each designed to record predetermined operating parameters of an existing technical system. The storage device is designed to receive and to store the operating parameters recorded by the number of recording devices. The configuration device is designed to receive predefined specifications for a technical system to be newly designed. The configuration device is furthermore designed to read the operating parameters stored in the storage device. The configuration device is furthermore designed to use the predefined specifications and the stored operating parameters to determine a configuration for the technical system to be newly designed.

According to a further aspect, what is provided is a method for configuring a technical system. The method comprises a step of recording predetermined operating parameters of a number of one or more existing technical systems. The method furthermore comprises a step of storing the recorded operating parameters in a central storage device. The method furthermore comprises a step of receiving predefined specifications for a technical system to be newly designed, of reading the operating parameters stored in the storage device and of determining a configuration for the technical system to be newly designed. The configuration for the technical system to be newly designed is determined in particular using the predefined specifications and the stored operating parameters.

Embodiments of the present invention are based on the finding that, when planning and dimensioning technical systems, in particular when planning and dimensioning technical installations, the configuration and the selection of the required operating parameters play a decisive role. A configuration with excessive safety margins in particular leads to increased expenditure and therefore is connected to a larger required installation space, and to increased costs. On the other hand, underdimensioning resources that are used may lead to premature failure or damage to the installation to be designed. Embodiments of the present invention are furthermore based on the finding that, especially in the case of technical systems or installations to be designed individually, very often only little knowledge is available about the operating behavior of the respective technical systems or installations. It is thereby impossible, or at least possible only with great difficulty, to optimally configure a technical system to be newly designed.

One concept of embodiments of the present invention is therefore to take this finding into account and to improve the configuration of a technical system for planning and dimensioning purposes. For this purpose, there is provision for the operating behavior of pre-existing technical systems to be recorded, stored and evaluated automatically. It is thereby possible to obtain a database that is able to be evaluated and taken into consideration for a design of a new technical system. By accessing such a constantly growing database, it is thus possible to configure a technical system to be newly designed as optimally as possible. It is thereby possible to avoid both overdimensioning resources and underdimensioning, and thus avoid premature faults or failures. It is thereby possible to guarantee reliable operation of the technical system to be newly designed and in the process to dispense with excessive safety margins.

The configuration, to be determined, of the technical system to be newly designed may for example comprise a selection or at least a suggestion for a selection of a resource from a plurality of available resources. An optimally suited resource may thereby be identified in each case for each individual application case of a technical system to be newly designed. The configuration may furthermore also for example comprise an implementation of a corresponding temperature control system, for example heating system or cooling system for resources. By way of example, a forecast for the operating behavior of the technical system to be newly designed may be created on the basis of the data of pre-existing technical systems. Based on this forecast, a configuration, in particular a dimensioning of resources or the like, may then be defined. Such dimensioning may also for example comprise determining a suitable number of resources to be connected in parallel. Overloading of individual resources is thereby able to be avoided. Excessive redundancy may also be dispensed with. It is however understood that the database of the operating behavior of pre-existing technical systems may also be applied for any other parameters for configuring a technical system to be newly designed.

The recording device may in particular be designed for any desired and suitable type of recording of operating parameters of existing technical systems. By way of example, the recording device may continuously record predetermined operating parameters, such as for example an operating temperature or other operating parameters that are explained in even more detail below. The operating parameters may also possibly be recorded only after predefined limit values have been exceeded or fallen below. It is furthermore also possible to record the operating parameters following any other trigger event. The respective operating parameters may in this case be recorded for example at a predefined temporal recording rate and/or with a predefined accuracy. The sampling rate or accuracy may possibly be adjusted. In addition to physical properties, such as temperature, pressure, humidity, flow rate, power, voltage, current, etc., which are recorded for example by way of suitable sensors, the operating parameters may also comprise any other parameters, such as for example control variables, in particular setpoint values or the like. Interventions of a user, for example in order to set a particular operating state or the like, may furthermore also for example be recorded as operating parameters.

The recorded operating parameters may for example be transmitted directly to an external storage device. As an alternative, it is also possible to first of all pre-process the recorded operating parameters in the recording device. Irrelevant data may thereby for example be filtered out or eliminated, or any other pre-processing of the recorded operating parameters may take place.

The storage device may be any suitable storage device for storing the operating parameters of one or more technical systems. By way of example, the operating parameters may be transmitted to the storage device by way of a suitable communication interface, for example by way of a data network via a wired and/or wireless radio connection.

The storage device may first of all prepare or pre-process the received operating parameters. The storage device may furthermore store the received operating parameters and provide them for the evaluation by the configuration device. By way of example, the storage device may be a central memory in a cloud or the like. There may furthermore also be provision for the storage device to be provided in a particular protected area in order for example to protect the stored operating parameters against unauthorized access.

According to one embodiment, the operating parameters recorded by the recording devices comprise a minimum and/or maximum operating temperature of a resource, a threshold value being exceeded and/or fallen below, failure of a resource, in particular a time of the failure of the resource and possibly further data linked to the failure, a switched-on duration and/or switched-off duration of a resource, relative loading of a resource and/or a degree of use of a resource. Any other operating parameters of the existing technical systems may furthermore also of course be recorded. As already mentioned above, in addition to the physical properties, in particular physical parameters recorded by way of sensors, control variables, in particular setpoint value specifications or user inputs, may also be recorded. It is furthermore of course possible to record any other operating parameters of the existing technical systems.

According to one embodiment, the configuration device is designed to define a dimensioning of a module of a technical system to be newly designed using maximum loading of a corresponding module of an existing technical system. The maximum loading of the corresponding module of the existing technical system may be determined in particular using the stored operating parameters. By way of example, the configuration device may analyze the stored operating parameters in order to determine the maximum loading that has occurred in the corresponding technical systems. This maximum loading may be applied for example as a basis for the dimensioning of a module in a technical system to be newly designed. Maximum loading may be for example a maximum temperature that occurs, a maximum power, a maximum flow, or else average values or the like. By taking into consideration the actual operating values of pre-existing technical systems, the implementation of the technical system to be newly designed is able to be adjusted optimally to the expected operating conditions.

In one embodiment, the configuration device is designed to determine expected loading of a module of the technical system to be newly designed using the operating parameters stored in the storage device. The expected loading may be for example an expected average or maximum temperature, an average or maximum power, flow amounts or any other variable. Expected setpoint value specifications, switched-on durations or the like are furthermore optionally also possible. The expected loading may be estimated for example by analyzing the stored operating parameters of the pre-existing technical systems. By way of example, corresponding operating parameters of the pre-existing technical systems may be identified. These may for example be appropriately scaled, interpolated or estimated in another way in order to determine corresponding expected loading of the technical system to be newly designed.

According to one embodiment, the configuration device is designed to adjust the recording of the predetermined operating parameters of the existing technical systems. By way of example, the recording rate or the accuracy of the operating parameters to be recorded may be modified accordingly by the recording device. For this purpose, the configuration device may be coupled to the recording devices via an appropriate communication connection. The configuration device may thereby adjust or control the recording of the operating parameters in the existing technical systems, including at any later time. It is thereby possible for example to stop recording operating parameters if such operating parameters are possibly no longer of interest. It is likewise also possible to possibly initiate the recording of particular operating parameters at a later time. It is furthermore also possible to modify an existing recording of operating parameters in order for example to adjust the accuracy of the recording, possibly to set or to adjust trigger events that control the recording of operating parameters or to adjust any other parameters for the recording of the operating parameters.

According to one embodiment, the configuration device is designed to adjust the recording of the predetermined operating parameters in the existing technical systems using the predefined specifications for a technical system to be newly designed. By way of example, it may be established, by way of the configuration device, that precise or more precise knowledge about one or more operating parameters is required for the configuration of the technical system to be newly designed. In this case, the accuracy for the recording of the corresponding operating parameter may be adjusted by the recording devices. It may furthermore for example be established in the configuration device that one or more additional operating parameters are of interest in order to create a suitable configuration of the technical system to be newly designed. In this case, the recording of the desired additional operating parameters by the recording devices may be initiated by the configuration device. Any other modification of the recording of the operating parameters in the existing technical systems is furthermore of course also possible, in particular recording of operating parameters in technical systems that is triggered by the specifications for the technical system to be newly designed.

According to one embodiment, the number of recording devices in each case comprises a memory and a processing device. The memory is designed to store the recorded operating parameters. The memory of the recording device may in particular have the function of a buffer memory. The processing device is designed to compress the operating parameters stored in the memory. The processing device is furthermore designed to transmit the compressed operating parameters to the storage device. Compressing the operating parameters may in particular comprise any suitable processing of the operating parameters. By way of example, the compression may comprise filtering the recorded operating parameters in order to eliminate operating parameters that are possibly irrelevant or less relevant. The compression may furthermore also comprise combining a plurality of identical or similar values. The compression may possibly furthermore also comprise adjusting the recorded values to an alternative timebase and/or an alternative sampling accuracy. Any other methods for processing the recorded operating parameters, in particular for minimizing the data volume of the recorded operating parameters, are furthermore of course also possible.

The operating parameters may be transmitted from the processing device to the storage device in any suitable way. By way of example, the transmission may be performed by way of a wired communication connection. A wireless communication connection, for example a radio connection based on a suitable communication standard, for example GSM, UMTS, LTE, 5G or the like, is furthermore likewise possible.

According to one embodiment, the recording device is designed to transmit the predetermined operating parameters to the storage device continuously or at predetermined time intervals. It is thereby possible to constantly monitor the operating parameters of the pre-existing technical systems. The operating parameters may for example be transmitted to the storage device in real time. It is furthermore also possible to first of all buffer-store the operating parameters in a memory of the recording device and to transmit them, in each case in bundled form, to the storage device at predetermined times. A virtually continuous profile of the evolution of the monitored operating parameters is thereby able to be maintained in the storage device.

In one alternative embodiment, the recording device is designed to transmit the predetermined operating parameters when a predetermined event has been detected in the respective existing technical system. By way of example, the operating parameters may be transmitted from the recording device to the storage device when a predefined trigger event occurs. Such a trigger event may be for example a threshold value being exceeded or fallen below, a failure of a resource or any other event. The amount of data that arises, in particular the amount of data to be transmitted and to be stored in the storage device, is thereby able to be minimized.

According to one embodiment, the storage device comprises a classification device. The classification device may be designed to classify and/or to group the data provided by the recording device on the basis of predetermined criteria. The received operating parameters may thereby be pre-processed in the storage device. The storage device may in particular store the received operating parameters in a structured form according to the classification. The storage device is thereby able to provide the stored data in a manner structured according to the classification and efficiently for further processing.

According to one embodiment, the predetermined criteria for the classification comprise a spatial position of the respective existing technical system, a frequency of faults, a fault cause, a usage rate of the respective existing technical system and/or an operating state of the respective existing technical system. Any other criteria for classifying the recorded operating parameters are furthermore of course also possible.

According to one embodiment, the configuration device comprises a neural network. The neural network may in particular be designed to determine the configuration of the technical system to be newly designed. The configuration device may in this case be designed to train the neural network using the operating parameters stored in the storage device. The training of the neural network may be initiated for example based on a manual event. As an alternative, automatic training of the neural network based on predetermined events in one or more existing systems or based on the detection of a particular event in the operating parameters provided by the existing technical system is also possible. The neural network may furthermore also for example be trained automatically on a regular basis at predefined time intervals. Efficient creation of the configuration parameters for a technical system to be newly designed is thereby possible.

According to one embodiment, determining the configuration of the technical system to be newly designed comprises calculating a probability of failure for a predetermined resource of the technical system to be newly designed. The probability of failure may be calculated using the stored operating parameters. A dimensioning of a resource in the technical system to be newly designed may in particular be determined on the basis of the calculated probability of failure. The dimensioning may in particular also comprise implementing redundancy of a resource.

The above configurations and developments may be combined with one another as desired where this is viable. Further configurations, developments and implementations of embodiments of the invention also comprise combinations of features of embodiments of the invention that are described above or below with respect to the exemplary embodiments but that have not been mentioned explicitly. A person skilled in the art will in this case in particular also add individual aspects to the respective basic forms of embodiments of the present invention as improvements or additions.

### BRIEF DESCRIPTION

Some of the embodiments will be described in detail, with reference to the following figures, wherein like designations denote like members, wherein:

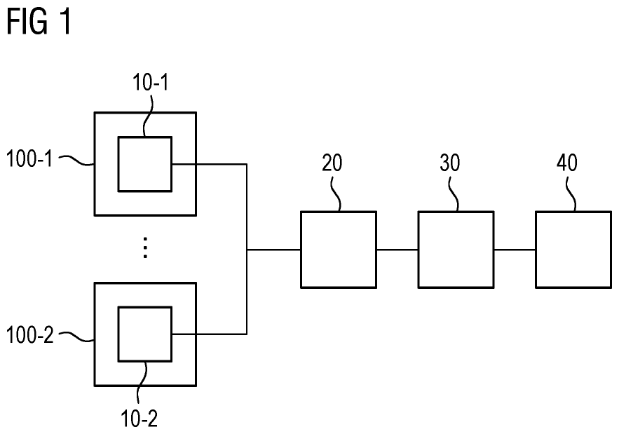

FIG. 1 shows a schematic illustration of a block diagram of an arrangement for configuring a technical system according to one exemplary embodiment;

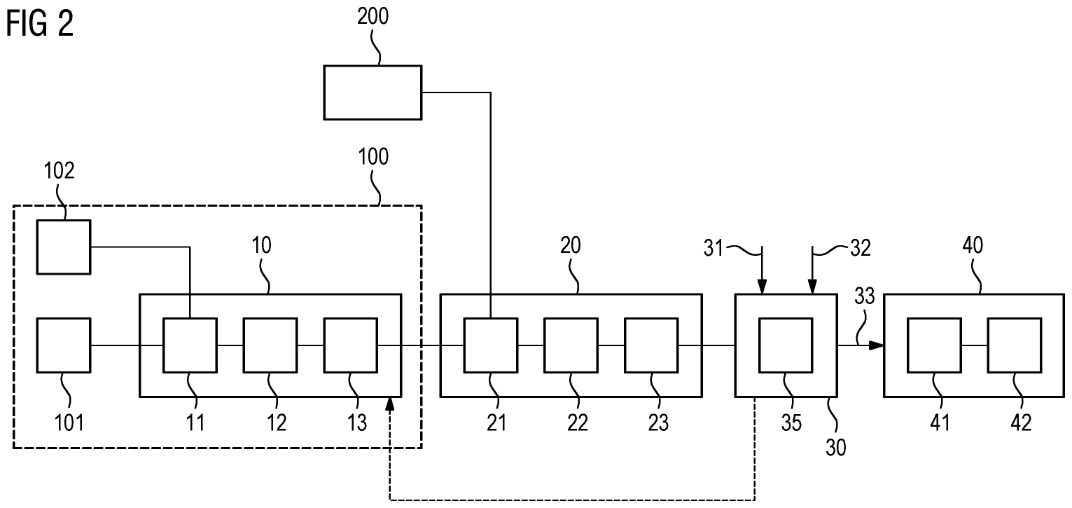

FIG. 2 shows a schematic illustration of a block diagram of an arrangement for configuring a technical system according to another exemplary embodiment;

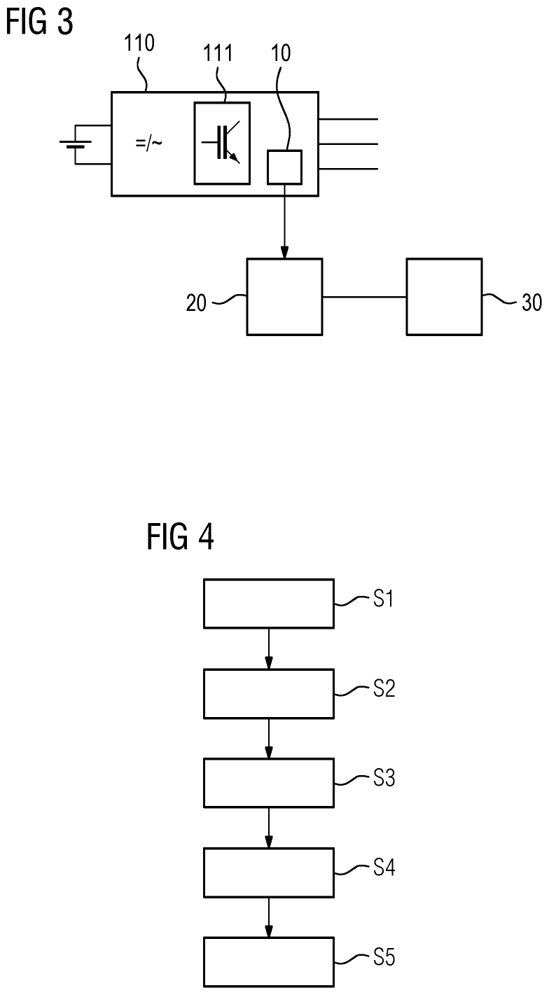

FIG. 3 shows a schematic illustration of a block diagram of an arrangement for configuring a technical system according to yet another exemplary embodiment; and

FIG. 4 shows a schematic illustration of a flowchart underlying a method for configuring a technical system according to one embodiment.

### DETAILED DESCRIPTION

FIG. 1 shows a schematic illustration of a block diagram of an arrangement for configuring a technical system according to one embodiment. The arrangement in this example comprises a plurality of recording devices 10-i, a storage device 20 and a configuration device 30. Each of the recording devices 10-i may for example be provided in an existing technical system 100-i. The number, illustrated here, of just two technical systems 100-i each having a recording device 10-i serves only for understanding. Any other number of technical systems 100-i having recording devices 10-i is furthermore also possible. Any larger number of technical systems 100-i each having a recording device 10-i may in particular be monitored. Further data may furthermore also be provided by recording devices 10-i that are not provided directly in or on an existing technical system 100-i. By way of example, data may additionally also be provided by external recording devices, for example a weather station or the like. Information about external influences that have an effect on the operation of an existing technical system 100-i may thereby also be recorded.

The existing technical systems 100-i may be any technical systems, in particular any technical installations. By way of example, the technical systems 100-i may be power plants for generating electric power, substation installations, power converters, for example inverters for converting DC voltage into a single-phase or multiphase AC voltage, technical installations for manufacturing particular products, for example production installations in the paper industry, production installations for any other products, installations in the chemical industry, or any other technical installations. It is understood that the application to the design of technical systems is not restricted to the individual cases described above. Rather, any technical systems or installations may be designed and configured accordingly.

Numerous operating parameters of the existing technical systems 100-i may be recorded during the operation of the respective technical systems 100-i. For this purpose, sensors that record one or more physical parameters within the respective technical system 100-i may for example be provided. Control commands between individual components of the respective technical system 100-i may furthermore also be logged. Such control commands may be exchanged between individual components of the respective technical system 100-i. Control commands or setpoint value specifications may furthermore also be issued to components of the technical system 100-i by a central control station. Any other operating parameters of the technical system 100-i may in principle also be recorded and provided to the respective recording device 10-i. The operating parameters may be provided directly to the respective recording device 10-i in the form of digital data. As an alternative, analog signals may also be provided to the recording device 10-i, and the analog signals may be converted into digital signals by way of a suitable analog-to-digital converter (not illustrated). The further processing of the recorded operating parameters in the recording device 10-i is explained in even more detail further below.

The recorded operating parameters may be transmitted from the recording devices 10-i of the respective technical systems 100-i to a central storage device 20. By way of example, the recording devices 10-i may be connected to the storage device 20 via a suitable communication connection, for example a wired or wireless connection. By way of example, the transmission may take place via an Internet connection, in particular via a protected Internet connection such as for example a VPN tunnel or the like. The transmission may furthermore also take place at least partly via a wireless connection, in particular a radio connection, such as for example a mobile radio connection.

The storage device 20 may receive the respective operating parameters from the recording devices 10-i and store them. Before the operating parameters are stored, the received operating parameters may possibly first of all be pre-processed, for example categorized, classified or the like. This is explained in even more detail below.

The database, stored in the storage device 20, of the operating parameters of the existing technical systems 100-i may be used for the design of a new technical system. In this case, properties for a technical system to be newly designed may in particular be determined at least partly automatically, using the operating parameters stored in the storage device 20. This is explained in more detail below.

If the intention is to design a new technical system, then the required specifications for the technical system to be newly designed may be provided to the configuration device 30. These specifications may for example comprise desired properties of the technical system to be newly designed. By way of example, the specifications may comprise a desired (maximum) power of the system, in particular an electric power, a desired throughput of a certain amount of substance, an amount of a starting product, properties of input values, for example an input voltage, a maximum input power, amount or properties of substances that are provided as starting products or the like. Any other specifications are furthermore of course also possible. The specifications may in particular also for example comprise specifications for modules to be used, component parts or the like. Further specifications, such as for example properties regarding a planned location and boundary conditions linked thereto such as temperature, possible cooling power, etc. may likewise be specified.

The configuration device 30 may then compare the specified requirements for the technical system to be newly designed with the data regarding the operating parameters of the existing technical systems that are stored in the storage device 20. It is thereby possible for example to derive which components already in use are capable of meeting the requirements according to the specifications for the technical system to be newly designed. By way of example, it is possible to establish, from the operating parameters stored in the storage device 20, whether an output power required according to the specifications of the technical system to be newly designed is able to be achieved using one or more modules of pre-existing technical systems. Further boundary conditions, such as for example maximum heating that occurs, a cooling power linked thereto, etc., may in particular in this case also be taken into consideration. Frequencies of malfunctions and failures of component parts in pre-existing technical systems may furthermore for example be determined on the basis of the operating parameters stored in the storage device 20. A required redundancy of modules, which redundancy is required in order to achieve operational reliability required according to the specifications for the technical system to be newly designed, may for example be derived from these data. It is thereby for example possible to determine a required number of standby components required in order to replace modules that potentially fail, such that a desired maintenance interval for exchanging faulty components is able to be complied with. It is however understood that the examples mentioned here for the design and configuration of a technical system to be newly designed on the basis of the predefined specifications and the stored operating parameters of pre-existing technical systems are to be understood as being merely exemplary. Any other configurations and dimensioning, implementations, etc. may of course also be determined on the basis of predefined specifications for a technical system to be newly designed and data regarding the operating parameters of pre-existing technical systems.

Specifications for the configuration, implementation, dimensioning of modules, required redundancy, etc. of the technical system to be newly designed may in this case be determined fully or at least partly automatically by the configuration device 30. For this purpose, the configuration device 30 may read the stored operating parameters from the storage device 20 via a suitable data interface. The information about the specifications of the technical system to be newly designed may furthermore be provided to the configuration device 30 via suitable data interfaces. A manual input interface for specifying properties of the technical system to be newly designed is optionally also possible. The automatically created configuration of the technical system to be newly designed may be provided to an output interface of the configuration device 30. The automatically created parameters may possibly be edited manually. Automatic further processing, as far as automatic planning and dimensioning of the modules of the technical system to be newly designed, is furthermore also possible.

The configuration generated by the configuration device 30 for the technical system to be newly designed may then be used as a basis for the further engineering. The further engineering of the technical system to be newly designed may in particular be performed fully or at least partly automatically. For this purpose, the data of the configuration generated by the configuration device 30 may for example be fed to a planning device 40. The planning device 40 receives the data of the configuration from the configuration device 30 and creates required planning documents for the technical system to be newly designed. By way of example, the planning documents may comprise circuit diagrams, parameter lists or software structures.

Suitable templates may for example be provided for creating the planning documents in the planning device 40. These templates may for example be provided in an internal memory of the planning device 40 or by an external database. In order to create an electrical installation, such a template may for example comprise a circuit diagram or at least a basic structure of a circuit diagram. The planning device 40 may then automatically determine suitable component parts for the individual components of the circuit diagram on the basis of the configuration provided by the configuration device 30. The required component parts may possibly be dimensioned accordingly on the basis of the provided configuration. By way of example, a required number of redundant component parts may also be determined on the basis of the provided configuration. Any other steps for automatically planning the technical system to be newly designed are furthermore of course also possible.

FIG. 2 shows a schematic illustration of a block diagram of an arrangement for configuring a technical system according to another embodiment. The explanations already given above in connection with FIG. 1 also apply here.

As is able to be seen in FIG. 2, the recording device 10 may, in a technical system 100, have for example a reception device 11 that receives data regarding operating parameters of the existing technical system 100. The reception device 11 may for example be connected to a control station or a control device 101. In this case, the reception device 11 may receive control variables, in particular setpoint value specifications or the like, from the control device 101. The reception device 11 may furthermore be coupled to one or more sensors 102. Each of the sensors 102 may record one or more physical parameters within the technical system 100 and provide an analog or digital signal corresponding to the recorded variable. If the signal is provided in analog form, then the reception device 11 may for example comprise an analog-to-digital converter that converts the analog signal into digital data. Any other operating parameters of the existing technical system 100 may furthermore also be recorded by the reception device 11.

The recording device 10 may furthermore comprise a processing device 12. The processing device 12 may for example process the operating parameters recorded by the reception device 11 before transmitting them to the storage device 20. By way of example, the data of the received operating parameters may be compressed. The amount of data that needs to be transmitted from the recording device 10 to the storage device 20 is thereby able to be minimized. By way of example, the compression may comprise filtering irrelevant and/or redundant data. Any other temporal compression or a compression of the resolution of the information may furthermore also be performed. It is furthermore possible for example to record and/or to transmit only operating parameters that correspond to a predetermined trigger event. Operating parameters may thus for example be recorded and/or transmitted only when a predefined threshold value is exceeded or fallen below. Any other pre-processing of the recorded operating parameters prior to transmission to the storage device 20 is furthermore also possible.

In order to transmit the operating parameters from the recording device 10 to the storage device 20, the recording device 10 may for example have a suitable interface 13. By way of example, the interface 13 may be a network interface. The transmission from the recording device 10, in particular the interface 13, to the storage device 20 may for example take place via a wired connection. As an alternative, the transmission may also take place at least partly via a wireless connection, in particular a mobile radio connection or the like. In this case, the interface 13 may for example comprise a corresponding radio interface.

The storage device 20 may comprise a reception interface 21 that receives data of the operating parameters from the recording devices of the existing technical systems 100. In the same way as the interface 13 of the recording device 10, the reception interface 21 may implement a wired communication connection or a wireless radio connection.

As already mentioned above, in addition to the operating parameters from the existing technical system 100, such as the abovementioned values of the control device 101 and the sensors 102, further, in particular external data may also be recorded. These data may for example be provided by an external data source 200. The external data source 200 may transmit the corresponding data to the storage device 20 via a wired or wireless interface.

The external data source 200 may be any data source that provides information, in particular information in connection with the operation of the existing technical system 100. By way of example, the external data source may be a weather station that provides data regarding temperature, air pressure, air humidity, wind direction or wind speed, etc. The external data source 200 may furthermore also be a measurement point on a body of water that provides for example information about a water level, water temperature, flow speed or the like. Any other data sources are of course also possible depending on the application case. By way of example, data may also be provided by an external computer center, in particular a cloud or the like.

In the case of a power plant, such as for example a wind power plant or a solar power plant, information about wind speed, wind direction, solar insolation, etc. is thereby for example also able to be taken into consideration.

The storage device 20 may furthermore for example comprise a classification device 22. This classification device 22 may for example (pre)-process the received operating parameters. By way of example, the classification device 22 may group or classify the received operating parameters according to predetermined properties. The classification may for example be performed according to the properties of the operating parameters. By way of example, the operating parameters may be classified according to a spatial position of the respective existing technical system 100, a frequency of faults in the existing technical system, a fault cause, a usage rate of the respective existing technical system or an operating state of the respective technical system. Any other classifications of the received operating parameters are of course also possible. By way of example, in the received operating parameters, it may also be distinguished whether the operating parameters belong to a normal operating state or whether the operating parameters were recorded during a fault case. Operating parameters regarding particular operating states, for example a critical operating state, overloading of the respective technical system, idling of the technical system or the like may furthermore also be grouped.

The received and possibly further-processed operating parameters may then be stored in a memory 23 of the storage device 20.

In order to design a new technical system, the configuration device 30 may resort to the data stored in the memory 23 of the storage device 20. The technical system to be newly designed may furthermore for example be characterized by specifying individual requirements 31 for the technical system to be newly designed, as well as technical parameters 32 for the technical system to be designed and modules of the technical system. The configuration device 30 then compares the requirements 31, the technical parameters 32 and the recorded operating parameters of existing technical systems 100 with one another and then creates suitable configuration parameters 33 for the technical system to be newly designed. For this purpose, the probability of failure of components in existing technical systems, loading limits of modules in existing technical systems, and further information able to be derived from the operating parameters may for example be compared with the requirements of the technical system to be newly designed, as has already been described above.

By way of example, the configuration parameters 33 for the technical system to be newly designed may be determined by way of a neural network 35. In this case, the requirements 31 and the technical specifications 32 may for example be provided to the neural network 35 in the form of input variables. The neural network 35 may in this case be trained beforehand, for example by way of the recorded operating parameters of the existing technical systems 100.

It is furthermore possible for example to dynamically adjust the recording of the operating parameters in the existing technical systems 100. The operating parameters of the existing technical systems 100 may thereby also be recorded appropriately when the requirements for the design of a new technical system change over time. By way of example, requirements or specifications that require further operating parameters to be recorded in existing technical systems 100 may exist for the design of new technical systems. In the same way, it is also possible for the recording of operating parameters that were recorded originally to become superfluous over time. For this purpose, the recording of the operating parameters in the recording devices 10 may be adjusted, for example based on the configuration device 30. In this case, a time interval for the recording of the operating parameters, an accuracy for the recording of the operating parameters or a trigger event for the recording of the operating parameters may in particular also be adjusted.

The configuration parameters 33 generated by the configuration devices 30 may be forwarded to a planning device 40 in order to generate the required engineering documents. The planning device 40 may for example comprise a first device 41 for generating a system architecture and a second device 42 for generating the required engineering documents on the basis of the system architecture. The system architecture and/or the engineering documents may in this case be created fully or at least partly automatically based on the provided configuration parameters 33.

FIG. 3 shows a schematic illustration of a specific exemplary embodiment for the configuration of a technical system, using the example of a voltage converter 110. As is able to be seen in FIG. 3, a DC voltage, which is intended to be converted into a three-phase AC voltage by the voltage converter 110, is provided on the voltage converter 110. For this purpose, a plurality of semiconductor switching elements 111 are provided in the voltage converter 110. These semiconductor switching elements 111 however only have a limited service life. It should accordingly be expected that at least some of the semiconductor switching elements 111 will gradually exhibit a defect in the course of the operation of the voltage converter 110. A certain number of redundant semiconductor switching elements 111 are therefore provided in the voltage converter 110. These may take over the function of a defective semiconductor switching element 111 in the event of a defect with the semiconductor switching element 111. Defective semiconductor switching elements 111 are in this case replaced with new semiconductor switching elements during a regular maintenance interval. A sufficiently large number of redundant semiconductor switching elements 111 should therefore be provided in the voltage converter 110, such that reliable operation is able to be guaranteed between two planned maintenance operations. When designing a new voltage converter, a suitable number of redundant switching elements therefore has to be determined. For this purpose, the operation of existing voltage converters 110 may be monitored and logged. The operating data recorded in the process may be used to optimally configure a voltage converter to be newly developed.

A recording device 10 that monitors the function of the switching elements 111 is therefore provided in each case in existing voltage converters 110. The occurrence of a malfunction in a switching element 111 and the boundary conditions linked thereto may furthermore be recorded and logged. The information thereby recorded may be provided in the storage device 20. If the intention is now to design a new voltage converter, then the requirements for this new voltage converter may be compared with the operating parameters, stored in the storage device 20, of pre-existing voltage converters. It is thereby possible to estimate the probability of a malfunction occurring in semiconductor switches of the voltage converter to be newly designed. A suitable number of redundant switching elements to be provided in the voltage converter to be newly designed may accordingly be determined. By automatically recording the operating parameters in existing voltage converters and comparing the recorded operating parameters with the requirements for a voltage converter to be newly designed, it is thus possible to achieve an optimum implementation of the configuration for the voltage converter to be newly designed.

FIG. 4 shows a schematic illustration of a flowchart underlying a method for configuring a technical system. In step S1, predetermined operating parameters of a number of existing technical systems 100-i are recorded. In step S2, the recorded operating parameters are stored in a central storage device 20. In step S3, the predefined specifications for a technical system to be newly designed are received, and in step S4, the stored operating parameters are read from the storage device 20. In step S5, a configuration for a technical system to be newly designed may then be determined. The determination may take place using the predefined specifications and the stored operating parameters.

The method may in particular comprise a step of calculating a probability of failure for predetermined resources of the technical system to be newly designed. The probability of failure may be calculated using the stored operating parameters.

In summary, embodiments of the present invention relate to an optimized and automated design of technical installations to be planned individually. For this purpose, operating parameters are first of all recorded in pre-existing technical installations and stored centrally. If the intention is to plan a new technical installation, then the specifications for the new installation may be compared with the previously recorded operating parameters in order to efficiently generate an optimum configuration of the new technical installation.

Although the present invention has been disclosed in the form of preferred embodiments and variations thereon, it will be understood that numerous additional modifications and variations could be made thereto without departing from the scope of the invention.

For the sake of clarity, it is to be understood that the use of “a” or “an” throughout this application does not exclude a plurality, and “comprising” does not exclude other steps or elements.

1. An arrangement for configuring a technical system, having:
a number of recording devices, wherein each recording device is designed to record predetermined operating parameters of a respective existing technical system;
a storage device that is designed to receive and to store the operating parameters recorded by the number of recording devices; and
a configuration device that is designed to receive predefined specifications for a technical system to be newly designed, to read the operating parameters stored in the storage device, and to use the predefined specifications and the stored operating parameters to determine a configuration for the technical system to be newly designed.

2. The arrangement as claimed in claim 1, wherein the operating parameters comprise a minimum and/or maximum operating temperature of a resource, a threshold value being exceeded and/or fallen below, failure of a resource, in particular a time of the failure of the resource, a switched-on duration and/or switched-off duration of a resource, relative loading of a resource, a degree of use of a resource or mechanical loading of a resource.

3. The arrangement as claimed in claim 1, wherein the configuration device is designed to define a dimensioning of a module of the technical system to be newly designed using maximum loading of a corresponding module of an existing technical system, and
wherein the maximum loading of the corresponding module of the existing technical system is determined using the stored operating parameters.

4. The arrangement as claimed in claim 3, wherein the configuration device is designed to determine expected loading of a module of the technical system to be newly designed using the operating parameters stored in the storage device.

5. The arrangement as claimed in claim 1, wherein the configuration device is designed to adjust the recording of the predetermined operating parameters of the existing technical systems.

6. The arrangement as claimed in claim 5, wherein the configuration device is designed to adjust the recording of the predetermined operating parameters in the existing technical systems using the predefined specifications for a technical system to be newly designed.

7. The arrangement as claimed in claim 1, wherein the recording devices comprise a memory and a processing device,
wherein the memory is designed to store the recorded operating parameters, and
wherein the processing device is designed to compress the stored operating parameters and to transmit the compressed operating parameters to the storage device.

8. The arrangement as claimed in claim 1, wherein the recording device is designed to transmit the predetermined operating parameters to the storage device continuously or at predetermined time intervals.

9. The arrangement as claimed in claim 1, wherein the recording device is designed to transmit the predetermined operating parameters when a predetermined event has been detected in the respective existing technical system.

10. The arrangement as claimed in claim 1, wherein the storage device comprises a classification device that is designed to classify and/or to group the data provided by the recording device on the basis of predetermined criteria.

11. The arrangement as claimed in claim 10, wherein the predetermined criteria comprise a spatial position of the respective existing technical system, a frequency of faults, a fault cause, a usage rate of the respective existing technical system and/or an operating state of the respective existing technical system.

12. The arrangement as claimed in claim 1, wherein the configuration device comprises a neural network that is designed to determine the configuration of the technical system to be newly designed, and
wherein the configuration device is designed to train the neural network using the operating parameters stored in the storage device.

13. A method for configuring a technical system, having the steps of:
recording predetermined operating parameters of a number of existing technical systems;
storing the recorded operating parameters in a central storage device;
receiving predefined specifications for a technical system to be newly designed;
reading the operating parameters stored in the storage device; and
determining a configuration for a technical system to be newly designed using the predefined specifications and the stored operating parameters.

14. The method as claimed in claim 13, wherein the step of determining the configuration comprises calculating a probability of failure for a predetermined resource of the technical system to be newly designed, and wherein the probability of failure is calculated using the stored operating parameters.
